(19) United States
(12) Patent Application Publication
(10) Pub. No.: US 2002/0015288 A1
(43) Pub. Date: Feb. 7, 2002

(54) High performance thermal/mechanical interface for fixed-gap references for high heat flux and power semiconductor applications

(76) Inventors: Joseph T. Dibene II, Oceanside, CA (US); David H. Hartke, Durango, CO (US); Wendell C. Johnson, Long Beach, CA (US); Farhad Raiszadeh, San Diego, CA (US); Edward J. Derian, San Diego, CA (US); Jose B. San Andres, El Cajon, CA (US)

Correspondence Address: GATES & COOPER LLP, HOWARD HUGHES CENTER, 6701 CENTER DRIVE WEST, SUITE 1050, LOS ANGELES, CA, 90045, US

(21) Appl. No.: 09/910,524

(22) Filed: Jul. 20, 2001

Related U.S. Application Data
(60) Provisional application No. 60/219,506, filed on Jul. 20, 2000.
(60) Provisional application No. 60/219,813, filed on Jul. 21, 2000.
(60) Provisional application No. 60/232,971, filed on Sep. 14, 2000.
(60) Provisional application No. 60/251,222, filed on Dec. 4, 2000.
(60) Provisional application No. 60/251,223, filed on Dec. 4, 2000.
(60) Provisional application No. 60/251,184, filed on Dec. 4, 2000.
(60) Provisional application No. 60/266,941, filed on Feb. 6, 2001.
(60) Provisional application No. 60/277,369, filed on Mar. 19, 2001.
(60) Provisional application No. 60/287,860, filed on May 1, 2001.
(60) Provisional application No. 60/291,749, filed on May 16, 2001.
(60) Provisional application No. 60/291,772, filed on May 16, 2001.
(60) Provisional application No. 60/292,125, filed on May 18, 2001.
(60) Provisional application No. 60/299,573, filed on Jun. 19, 2001.
(60) Provisional application No. 60/301,753, filed on Jun. 27, 2001.

(51) Int. Cl. H05K 7/20

(52) U.S. Cl. 361/711

(57) ABSTRACT

? A thermal mechanical interface usable between a heatsink and a heat dissipating device is disclosed. In one embodiment, the thermal mechanical interface comprises a thermally conductive mechanically resilient member having a corrugated cross section and a first thermal conductance, disposed between the heat sink and the heat dissipating device and a thermal interface material having a second thermal conductance, disposed within the corrugated cross section.

### BACKGROUND OF THE INVENTION

1. Field of the Invention

The present invention relates to systems and methods for cooling heat dissipating devices, and in particular to a thermal/mechanical substrate aiding in thermal transfer between high heat flux devices, such as microprocessors, and heatsinks where the thermal interface is a fixed gap reference.

2. Description of the Related Art

High performance electronic devices typically generate large amounts of heat due to their power consumption requirements. To dissipate heat generated from such devices, a large heatsink is usually thermally coupled to a surface of the device. Often, due to the mass of the heatsink (due to the large amount of heat that must be dissipated) and due to other electrical and/or mechanical factors, the heatsink may be thermally coupled to the device via a thermal interface material (TIM). The TIM is usually a grease or some compliant wetting material which helps to conduct the heat from one surface to the other.

Unfortunately, when the device and the heat sink are arranged in a stackup configuration (disposed along a vertical or z-axis with respect to one another), the separation between the device lid (or die) and the heat sink is subject to assembly and fabrication tolerances. These tolerances can lead to inadequate heat conduction through the TIM, especially where the TIM comprises a thermal grease or similar material.

What is needed is a device which is sufficiently compliant to take up the tolerances in the stackup between the heatsink base and device lid (or die) yet still conduct heat adequately (and predictably) between the two surfaces. The device should also force a low interfacial resistance via a constant force applied between the heat source and the heat sink. Further, the device should be simple to apply, cost effective, and reliable. The present invention satisfies that need.

### SUMMARY OF THE INVENTION

To address the requirements described above, the present invention discloses thermal mechanical interface usable between a heatsink and a heat dissipating device. In one embodiment, the thermal mechanical interface comprises a thermally conductive mechanically resilient member having a corrugated cross section and a first thermal conductance, disposed between the heat sink and the heat dissipating device and a thermal interface material having a second thermal conductance, disposed within the corrugated cross section.

The present invention provides a structure whereby a thermally conductive material is applied to a thermally conductive substrate that is then placed between a heat source and a heatsink. In one embodiment, the structure includes a specially formed highly conductive metallic substrate (such as copper or aluminum) that is formed in a corrugated cross section (sinusoidal, trapezoidal or otherwise) to create a spring which is compressible in the z-axis, thus allowing for tolerances between the heat sink and the device. When compressed, the spring keeps a constant low interfacial resistance between the thermal load (the heat sink or other heat dissipating device) and source (the device or element thermally coupled to the device) while acting as an effective thermal transfer mechanism. The thermal/mechanical substrate (TMS) also takes up the tolerance in the mechanical stackup between the electronic device and the heatsink. In one embodiment, the device limits ‘pump-out’ of the grease material by containing much of the grease in the wells formed by inflections in the substrate. Additionally, the TMS may be fabricated to include inflections of selective pitch and density over specific parts of an electronic device or silicon die to help spread the heat better in devices where the heat is concentrated in regions of the die itself.

### BRIEF DESCRIPTION OF THE DRAWINGS

Referring now to the drawings in which like reference numbers represent corresponding parts throughout:

FIGS. 1A and 1B are diagrams of a circuit board assembly;

FIG. 2 is a diagram showing the geometry of one embodiment of the TMS;

FIGS. 3A-3D are diagrams showing top and cross sectional views of different embodiments of the TMS;

FIG. 4 is a diagram showing a TMS with a multi-layer construction; and

FIG. 5 is a diagram showing how the TMS may be fabricated.

### DETAILED DESCRIPTION OF PREFERRED EMBODIMENTS

In the following description, reference is made to the accompanying drawings which form a part hereof, and which is shown, by way of illustration, several embodiments of the present invention. It is understood that other embodiments may be utilized and structural changes may be made without departing from the scope of the present invention.

The present invention makes use of a thermally conductive member fabricated with a material of much higher conductivity than a TIM of similar dimensions. For example, the thermally conductive member can be fabricated of copper having a conductivity at or greater than 380 watts per meter-degree Kelvin (W/m-K?), and the TIM can be a thermal grease (in which the conductivity generally does not exceed 4 (W/m-K?).

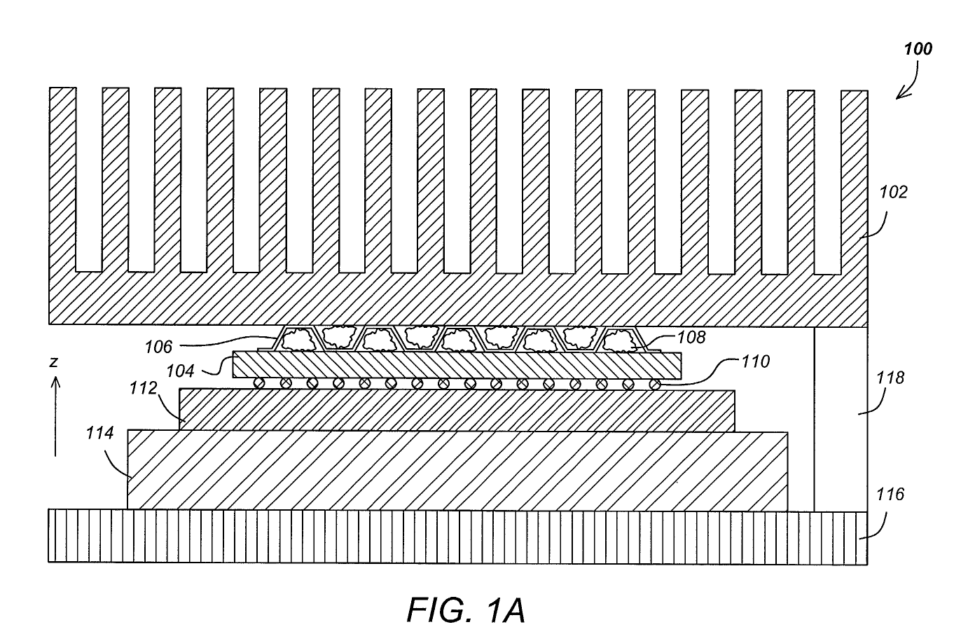

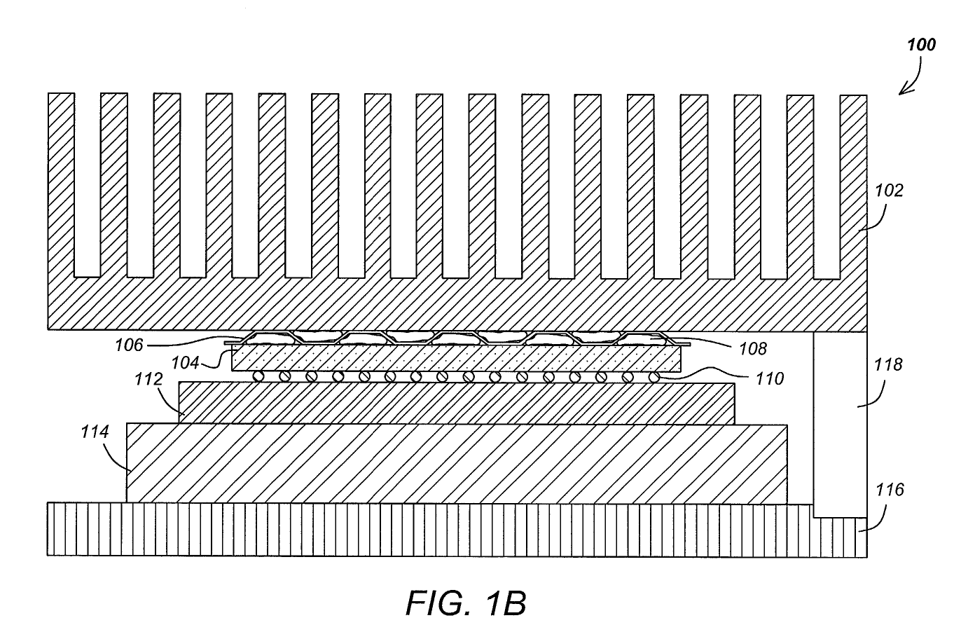

FIG. 1A is a diagram of a circuit board assembly 100. The circuit board assembly comprises a heatsink 102 and a heat dissipating electronic device 104 such as a silicon die. A thermal/mechanical substrate (TMS) 106 is disposed between the heatsink 102 and the electronic device 104. In one embodiment, the TMS 106 is a thermally conductive (typically in excess of 300 W/m-K?) and mechanically resilient or compressible member having a corrugated cross section. Also, the TMS 106 may include thermal interface material 108 disposed in the inflections in the corrugated inflections.

The electronic device 104 is mounted to a substrate 112 via a ball grid array 110 or equivalent to a substrate 112 to provide electrical communication between circuit traces and elements in the substrate 112 with the electronic device 104. The substrate is mounted to a socket 114 and to a printed circuit board (PCB) 116, thus providing electrical communication between the PCB 116 and the electronic device 104. In one embodiment, a mechanical base 118 may be provided to fix the gap between the heat sink 102 and the electronic device 108. The variability in the gap may be significant, typically between 2 and 14 mils.

FIG. 1B is a diagram illustrating a circuit board assembly 100 in which the gap between the heat sink 102 and the electronic device 108 is thinner than that which is illustrated in FIG. 1A. In this configuration, the TMS 106 is compressed along the z-axis, and may move laterally (perpendicular to the z-axis) a small amount, allowing the TMS 106 to allow for said compression.

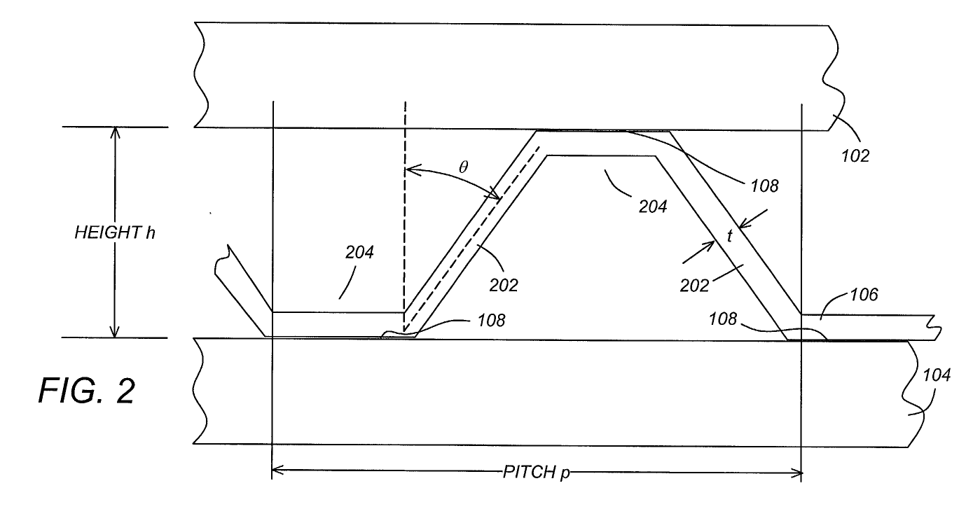

FIG. 2 is a diagram showing the geometry of one embodiment of the TMS 106. The TMS 106 includes a plurality of beams 202 coupled at inflections 204, thereby creating a corrugated cross section. Thermal conductance can be improved by the use of TIM 108 between the TMS 106 and the heatsink 102 and/or the electronic device 104.

The effective conductivity K of the TMS 106 is a function of the beam thickness of the TMS 106 (t) divided by the pitch (p) (distance between successive surface contact points) and the height (h) times the cosine of the angle (θ) (from vertical) between the TMS 106 beam and the surface of the electronic device 108 surface, or:

K α(2·t/p·h) cos θ

There is an inherent balance between the thickness and the stiffness of the TMS 106 (e.g., all other things equal, a thicker TMS 106 will be stiffer). If the TMS 106 beam is too stiff, or there are many beams 202, the spring constant of the TMS 106 along the z-axis (and hence the resulting force applied between the heat sink 102 and the electrical device 108) will be too great and may damage the device 108 when the TMS 106 is compressed. Conversely, if there are very few beams 202 to weaken the structure, the effective thermal conductivity will be reduced which may inhibit the ability to cool the device.

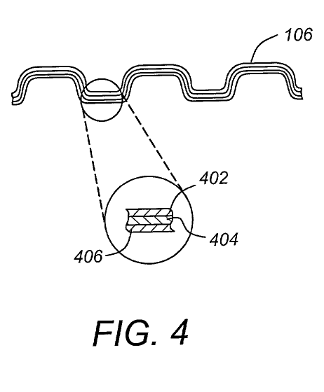

In addition, the TMS 106 preferably has robust spring characteristics (suitable spring constant and sufficient strength to prevent permanent deformation). Typically, good thermal conductors such as pure copper, do not exhibit such characteristics. To combat this problem the beam may be tri-forcated (as described below with respect to FIG. 4) such that the TMS 106 includes a multi-layer construction of copper/steel/copper. This embodiment minimally impacts the thermal characteristics but dramatically improves the mechanical characteristics. Furthermore, the TMS 106 may be weakened to reduce the spring force but not substantially impact thermal conductivity by selectively placing holes or slots in the substrate in specific regions while maintaining a small pitch (e.g., many beams 202).

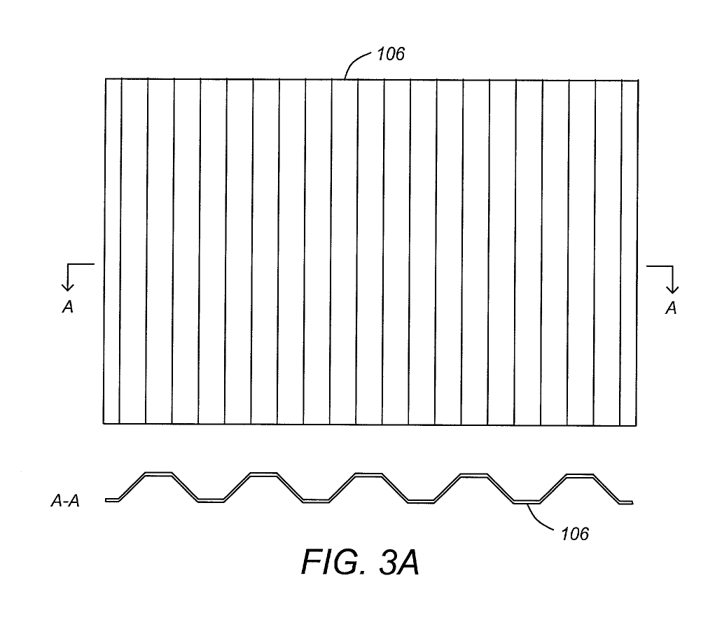

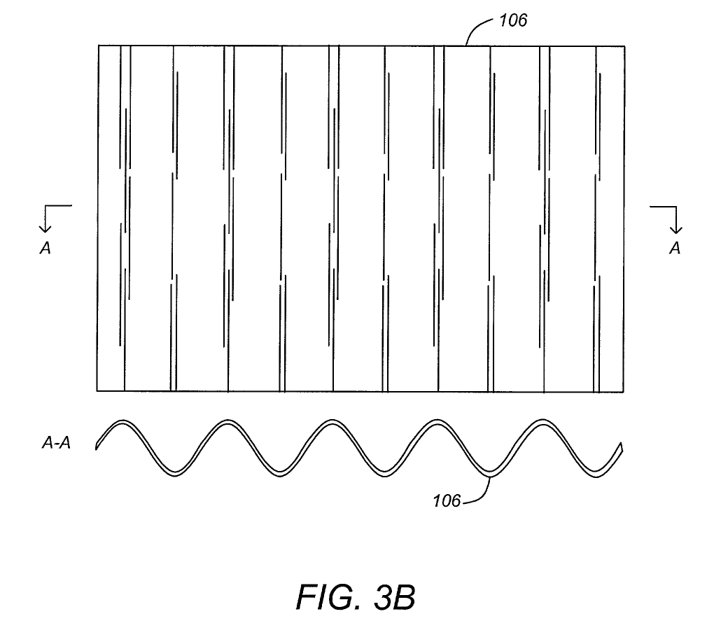

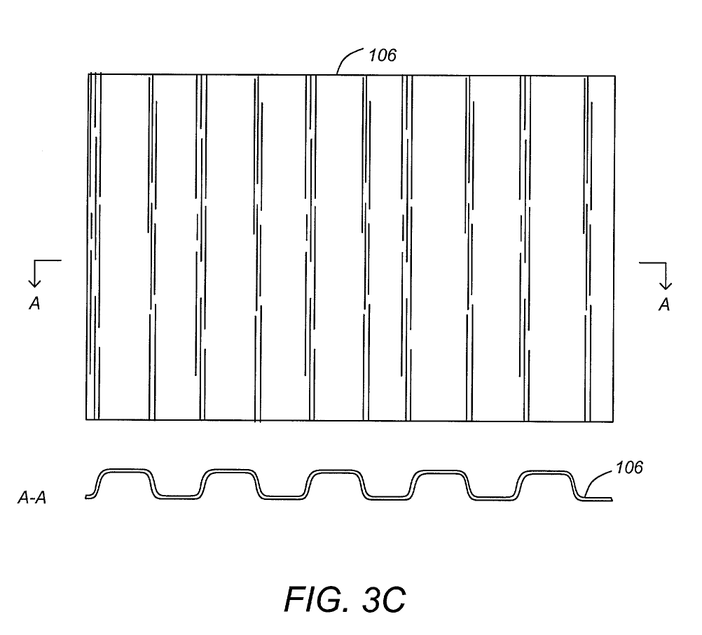

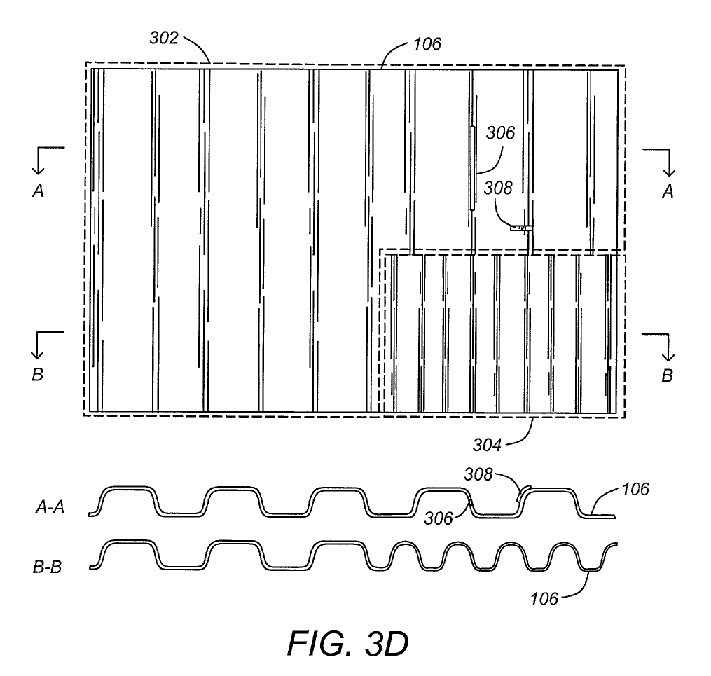

FIGS. 3A-3D show top and cross section views of the TMS 106. FIG. 3A presents a TMS 106 having a trapezoidally corrugated cross section. A thermally conductive wetting material, such as a grease or phase-change TIM, can also be applied to surfaces of the TMS 106. In one embodiment, the TIM is applied to all surfaces of the TMS 106. In another embodiment, the TIM is applied primarily to areas 302A and 302B proximate inflection points where the material will be under a constant force to reduce interfacial resistance between the heat source and heat sink.

FIG. 3B presents a TMS 106 having a sinusoidally corrugated cross section.

FIG. 3C presents a TMS 106 having a rounded square corrugated cross section.

FIG. 3D presents a TMS having two different corrugated cross sections, a first corrugated cross section 302 and a second corrugated section 304. The first corrugated section 302 may include a corrugated section of the same shape but a different period (or pitch) than the second corrugated section 304. Or, the first corrugated section 302 and the second corrugated section 304 can have different shapes, periods, pitches, angles, and/or height. This permits the accommodation of different mechanical or thermal characteristics of the portions of the heat sink 102 and/or the component 104 which contact the TMS 106 at those portions. For example, the reduced pitch in second corrugated section 304 provides a greater density of TMS 106 beams. This may be usefully applied adjacent to a higher heat flux region for spot heating within a die.

FIG. 3D also illustrates that the mechanical characteristics of the TMS 106 can be altered by including surface features such as holes, slots 306 or dimples 308 in or on the TMS 106. Holes and/or slots will tend to reduce the effective spring constant of the TMS 106 along the z-axis, while dimples can be used to increase the spring constant if desired.

FIG. 4 is a diagram showing a TMS 106 with a tri-forcated construction. In this embodiment, the TMS 106 includes multiple layers (two or greater) sandwiched together. In the illustrated embodiment, the TMS 106 includes a first layer 402, a second layer 404 and a third layer 406. In one embodiment, the first layer 402 and the third layer 406 comprise a material with desirable thermal characteristics (e.g. a higher thermal conductivity) than the second layer 404, such as copper, while the second layer comprises a material with desirable mechanical characteristics (strength and modulus of elasticity) such as stainless steel. While FIG. 4 illustrates an embodiment with three layers, two layers or greater than three layers may also be used.

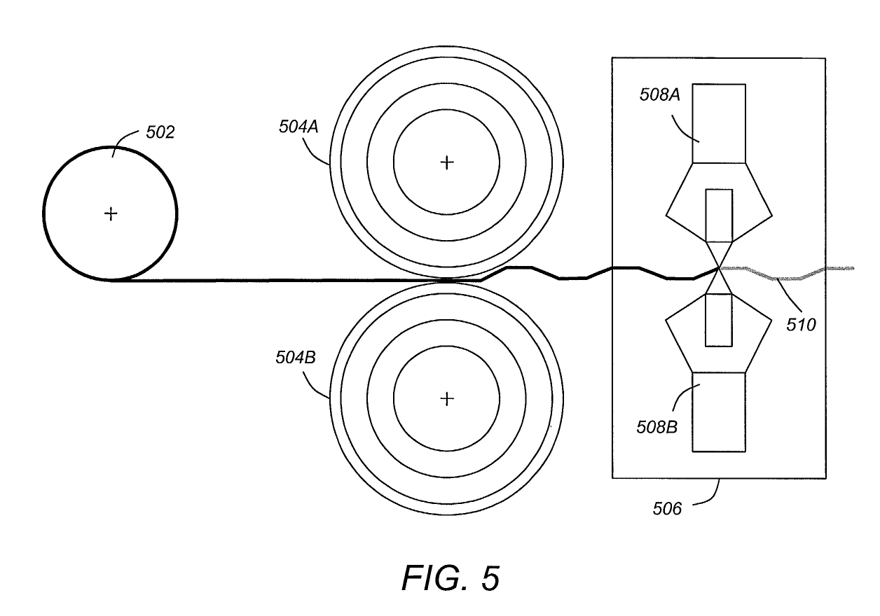

FIG. 5 is a diagram showing how the TMS may be fabricated. The TMS may be fabricated by starting with a roll of sheet metal material of the appropriate thickness on a spool 502 and feeder. The TMS material is fed into two rollers 504A and 504B which bend the fed material the desired corrugated shape (the trapezoidal shape is illustrated) for optimal thermal/mechanical performance. In one embodiment, this is accomplished by the use of rollers 504A and 504B having complementary and cooperating surfaces that, when pressed together with the material therebetween, bend the material into the desired shape.

A TIM (such as a grease) is applied to one or both sides with a dispenser system 506. In one embodiment, the dispenser system 506 includes a first TIM dispenser 508A to apply TIM to a first side of the TMS and a second TIM dispenser 508B to apply TIM to a second side of the TMS. After the TIM is applied to the TMS, the material 510 may then be packaged to protect the applied grease and then cut to size for application. Should high assembly pick-and-place of the completed TMS be necessary, small holes or tabs may be fabricated on or in the TMS using the foregoing process to allow ease of grabbing and placing the TIM during final assembly.

### CONCLUSION

This concludes the description of the preferred embodiments of the present invention. The foregoing description of the preferred embodiment of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto. The above specification, examples and data provide a complete description of the manufacture and use of the composition of the invention. Since many embodiments of the invention can be made without departing from the spirit and scope of the invention, the invention resides in the claims hereinafter appended.

What is claimed is:

1. A circuit board assembly, comprising:
a heat dissipating device;
a heat sink; and
a thermally conductive mechanically resilient member having a corrugated cross section and a first thermal conductance, disposed between the heat sink and the heat dissipating device.

2. The circuit board assembly of claim 1, wherein:
the heat sink is disposed along a z-axis from the heat dissipating device, thereby defining a space therebetween of variable height; and
wherein the thermally conductive mechanically resilient member is springingly compressible along the z-axis.

3. The circuit board assembly of claim 2, farther comprising: a thermal interface material having a second thermal conductance, disposed within corrugated cross section.

4. The circuit board assembly of claim 3, wherein the corrugated cross section includes a plurality of inflections and the thermal interface material is disposed proximate at least a portion of the inflections.

5. The circuit board assembly of claim 3, wherein the second thermal conductance is smaller than the first thermal conductance.

6. The circuit board assembly of claim 3, wherein the first thermal conductance is between 200 and 400 w/m-K.

7. The circuit board assembly of claim 3, wherein the second thermal conductance is between 2 and 6 W/m-K.

8. The circuit board assembly of claim 3, wherein the thermally conductive mechanically resilient member is metallic.

9. The circuit board assembly of claim 3, wherein the corrugated cross section is sinusoidal.

10. The circuit board assembly of claim 3, wherein the corrugated cross section is trapezoidal.

11. The circuit board assembly of claim 3, wherein the thermally conductive mechanically resilient member includes a second corrugated cross section.

12. The circuit board assembly of claim 3, wherein the first corrugated cross section is periodic according to a first period and the second corrugated cross section is periodic according to a second period less than the first period.

13. The circuit board assembly of claim 3, wherein the thermally conductive mechanically resilient member comprises:
a first layer comprising a first thermally conductive material; and
a second layer comprising a second thermally conductive material.

14. The circuit board assembly of claim 13, further comprising:
a third layer comprising a third thermally conductive material.

15. The circuit board assembly of claim 14, wherein the first thermally conductive material and the third thermally conductive material include a higher thermal conductivity than the second thermally conductive material.

16. The circuit board assembly of claim 14, wherein the second thermally conductive material comprises a higher strength than the first conductive material and the second conductive material.

17. The circuit board assembly of claim 14, wherein the third thermally conductive material and the first thermally conductive material include copper.

18. A thermal interface, for transferring heat from a heat dissipating device and a heat sink, comprising:
a thermally conductive mechanically resilient member having a corrugated cross section and a first thermal conductance, the member disposed between the heat sink and the heat dissipating device; and
a thermal interface material having a second thermal conductance, disposed within the corrugated cross section.

19. The thermal interface of claim 18, wherein:
the heat sink is disposed along a z-axis from the heat dissipating device, thereby defining a space therebetween of variable height; and
wherein the thermally conductive mechanically resilient member is springingly compressible along the z-axis.

20. The thermal interface of claim 18, wherein the corrugated cross section includes a plurality of inflections and the thermal interface material is disposed proximate at least a portion of the inflections.

21. The thermal interface of claim 18, wherein the second thermal conductance is smaller than the first thermal conductance.

22. The thermal interface of claim 18, wherein the first thermal conductance is between 200 and 400 W/m-K.

23. The thermal interface of claim 18, wherein the second thermal conductance is between 2 and 6 W/m-K.

24. The thermal interface of claim 18, wherein the thermally conductive mechanically resilient member is metallic.

25. The thermal interface of claim 18, wherein the corrugated cross section is sinusoidal.

26. The thermal interface of claim 18, wherein the corrugated cross section is trapezoidal.

27. The thermal interface of claim 18, wherein the thermally conductive mechanically resilient member includes a second corrugated cross section.

28. The thermal interface of claim 18, wherein the first corrugated cross section is periodic according to a first period and the second corrugated cross section is periodic according to a second period different than the first period.

29. The thermal interface of claim 18, wherein the thermally conductive mechanically resilient member comprises:
a first layer comprising a first thermally conductive material;
a second layer comprising a second thermally conductive material; and

30. The thermal interface of claim 29, further comprising:
a third layer comprising a third thermally conductive material.

31. The thermal interface of claim 30, wherein the first thermally conductive material and the third thermally conductive material include a higher thermal conductivity than the second thermally conductive material.

32. The thermal interface of claim 30, wherein the second thermally conductive material comprises a higher strength than the first conductive material and the second conductive material.

33. The thermal interface of claim 30, wherein the third thermally conductive material and the first thermally conductive material include copper.

34. A method of producing a thermal interface, for transferring heat from a heat dissipating device to a heat sink, comprising the steps of:
corrugating a thermally conductive member having a first thermal conductance; and
applying a thermal interface material having a second thermal conductance to the corrugated thermally conductive member.

35. The method of claim 34, wherein the step of corrugating a thermally conductive member comprises the step of passing the thermally conductive member between a first roller having a first surface and a second roller having a second surface complementary and cooperating with the first surface to bend material passing between the first surface and the second surface.

36. The method of claim 34, wherein the second thermal conductance is lower than the first thermal conductance.

37. The method of claim 34, wherein the thermal interface material is applied proximate inflections formed by the corrugated thermally conductive member.
